(19) United States
(12) Patent Application Publication
(10) Pub. No.: US 2007/0096165 A1
(43) Pub. Date: May 3, 2007

(54) In-situ wet chemical process monitor

(76) Inventors: Bruce A. Lipisko, Encinitas, CA (US); Robert T. Talasek, Meadowlakes, TX (US)

Correspondence Address: RICHARD L. BIGELOW, 203 TREMONT STREET, NEWINGTON, CT, 06111, US

(21) Appl. No.: 11/586,174

(22) Filed: Oct. 25, 2006

Related U.S. Application Data
(60) Provisional application No. 60/731,112, filed on Oct. 28, 2005.

(51) Int. Cl. H01L 23/58; H01L 21/00

(52) U.S. Cl. 257/253; 438/49

(57) ABSTRACT

This invention relates to a device intended to perform various chemical determinations in several wet chemical processes commonly used in semiconductor applications, including, but not limited to, those referred to as front end of line (FEOL) cleans, back end of line (BEOL) cleans, and copper electroplating. The device provides continuous or near continuous sensing of critical parameters such as component concentrations and metallic impurity concentrations. The device is capable of storing data for transmission after completion of the process, or transmitting data in real time as it is acquired. The device makes use of ISFET's and ChemFET's coupled with reference electrodes to detect small variations in the chemical properties of various wet chemical processes. The device can further either store the data for later analyses or transmit the data in real or near real time for more temporal analysis and control.

### CROSS REFERENCE TO RELATED APPLICATIONS

This non-provisional patent application claims priority based on U.S. Provisional Patent Application 60/731,112 filed on Oct. 28, 2005.

### FEDERAL RESEARCH STATEMENT

None

### BACKGROUND OF THE INVENTION

1. Field of the Invention

This invention relates to a device intended to perform various chemical determinations in several wet chemical processes commonly used in semiconductor applications, including, but not limited to, those referred to as front end of line (FEOL) cleans, back end of line (BEOL) cleans, and copper electroplating. The device provides continuous or near continuous sensing of critical parameters such as component concentrations and metallic impurity concentrations. The device is capable of storing data for transmission after completion of the process, or transmitting data in real time as it is acquired.

2. Description of the Related Art

The current state of wet process metrology represents two opposite ends of a spectrum. One end of the spectrum is the very low technology techniques historically used to monitor wet processes, especially immersion systems. These include very straightforward approaches such as adding an excess of the active ingredient at predefined intervals. An alternative but also widely used control methodology entails simply counting the number of wafers that have been processed in the bath and then dumping the bath after a pre-determined number of wafers is reached.

On the other end of the spectrum, wet process chemicals are routinely analyzed using very sophisticated analytical instruments, such as Infrared Spectrophotometers, Mass Spectrophotometers and Liquid Chromatographs. These instruments provided highly accurate data in many cases analyzing to the parts per billion level.

Neither of these approaches provides the level of control required as the industry moves towards 64 nm and 45 nm processes.

The low technology approach that has evolved over the years simply does not offer real time control. Using these approaches it is entirely possible for a process to be out of specification for an extended period of time before any action is taken. Historically wet processes have been robust enough to function within these limitations but that is no longer the case.

The second general approach, using analytical instruments, provides, as noted highly accurate data. But analytical analysis is typically very expensive on a per sample basis and extremely time consuming. Most analyses require that a sample be drawn from a bath and then “prepped” by a competent chemist or technician. The complete analysis takes hours if not days to complete, rendering the results interesting for historical perspective but not useful for real time process control.

There is a clear need for an accurate, yet low cost real time capability for measuring various components and impurities in chemical baths.

The following prior art is noted in relation to this application.

European Patent EP0615125 to Birot et al describes a method of construction for ESFETs and an application for measurement of pH in seawater. However, Birot does not disclose the configuration of elements that allows for the accurate, low cost, real time capability for measuring components and impurities in chemical baths that the instant invention presents.

U.S. Pat. No. 5,911,873 to McCarron et al teaches circuitry and a method of operation of an ISFET to allow real-time diagnostics of a solution. McCarron apparently restricts itself to use of a standard glass reference electrode whereas the instant invention utilizes a REFET. McCarron teaches operating the ISFET at multiple source drain biases and multiple drain currents to obtain additional information about the performance of the ISFET. The present invention described herein is used to characterize small changes in a well-controlled system. Therefore, only one source drain bias and one drain current is required.

U.S. Pat. No. 6,948,388 to Clayton et al describes a method for wireless transmission of simple signals such as those associated with an ISFET. While Clayton teaches a fairly complex method of signal transmission, it is not in conflict with the instant invention which uses commercially available signal transmission devices.

US Patent Application 2004/0132204 by Chou et al discloses a handheld device that measures pH in a solution. The instant invention eliminates the need for constant human interaction (i.e. a person holding the device) and allows for the device to be completely immersed in solution and send signals from said solution.

U.S. Pat. No. 6,624,637 to Pechstein teaches an immersed device with complex circuitry for sensing ion concentrations. The instant invention presents a much more simplified circuitry and includes a method for transmitting data. Pechstein teaches isolating the REFET from the operating solution with a diaphragm, whereas the present invention described herein exposes the REFET directly to the working solution. In addition, due to the small change in signal being measured in this invention, significantly more sophisticated amplification and noise suppression schemes will be required than that contemplated in Pechstein.

U.S. Pat. No. 6,353,323 to Fuggle teaches another method of measuring ion concentrations using an ISFET.

U.S. Pat. No. 6,290,838 to Mifsud et al presents an apparatus and method for combining multiple sensors.

U.S. Pat. No. 6,145,372 to Hall teaches an older method of sensing and monitoring chemical processes by using a bare silicon surface as a sensing electrode and standard reference electrodes. The use of ISFETs and a REFET in the instant invention is a significant evolution of the process and apparatus taught in Hall.

None of the above referenced prior art presents the unique combination of real time monitoring of chemical baths and simultaneous or nearly simultaneous transmission of information to a process controller that the instant invention does.

### SUMMARY OF THE INVENTION

The heart of the device is the sensor, called an Ion Sensitive Field Effect Transistor, or ISFET. These devices are commercially available and are used as pH sensors, primarily in the biotech and environmental fields, because of their durability and sturdy nature. As available, they can be used to monitor the concentration of most of the active component in the Front End Of The Line (FEOL) cleaning solutions, since the concentration of acids and bases in these solutions will affect the pH. There are literature references that suggest that an Ion Sensitive Field Effect Transistor (ISFET) whose sensor surface has been chemically modified (often referred to as a Chemical Field Effect Transistor [ChemFET]) can be used to monitor other chemical constituents, such as metallic impurities (of interest primarily in FEOL cleans), or organic molecules (of interest in Back End Of The Line (BEOL) cleans and copper electroplating.

The sensor requires a reference electrode. In most current applications, a standard reference electrode, such as a calomel (Hg/HgCl₂) or silver/silver chloride electrode is used. In their normal configuration, these electrodes are unsuitable for the form and function of the device described here. Two options exist that have both been cited in the literature. First, and most likely, is the use of a Reference Field Effect Transistor (REFET) combined with a metal counter electrode. In this approach, the REFET, which is an ISFET whose surface has been modified to make it insensitive to ions of interest, compensates for temperature and other drift effects, while the counter electrode handles any minor current flow and prevents the ISFET/REFET combination from being polarized. The second alternative is a miniaturized version of a more traditional reference electrode.

Simple commercially-available electronics will be used to detect and amplify the electrical signal, provide any simple logic required, and store the data. A commercially available transceiver (that is compatible with communication devices such as a Bluetooth) will transmit the data to a computer, PDA or process tool. Power to the device will be provided by a commercially available power source such as common alkali hydride “watch batteries”.

The form of the device will be a disc, with either a 200 mm or 300 mm diameter, approximately 5 mm thick, to allow the device to travel anywhere in the semiconductor manufacturing process that a standard silicon wafer could travel. In this manner, the device can be immersed in the solution it is monitoring. Alternatively the sensor assembly can be separated from the disc and mounted directly in the process chamber.

ISFETs, RFETs, and CHEMFETs are fairly well understood and well developed devices. The essence of the instant invention is the combination of these devices with current data transmission devices to allow real time or nearly real time monitoring and control of chemical processes.

### BRIEF DESCRIPTION OF DRAWINGS

FIG. 1 is an overhead cutaway view of the device.

FIG. 2 is an overhead cutaway schematic view of the sensor assembly.

FIG. 3 is a cutaway side view of the Ion Sensitive Field Effect Transistor (ISFET) assembly.

### DETAILED DESCRIPTION OF THE INVENTION

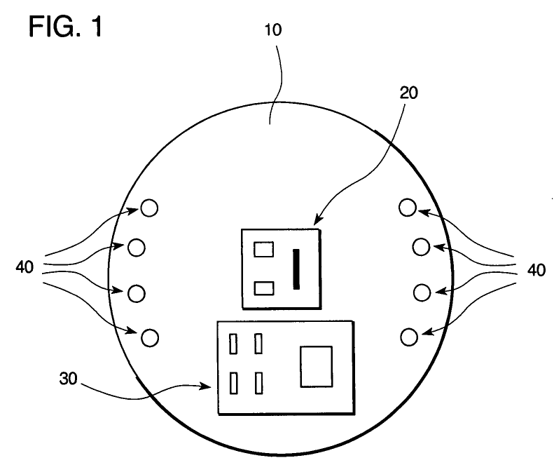

An overview of the preferred embodiment of the invention is illustrated in FIG. 1. Referring to FIG. 1, an overview of the device 10 is shown. The major components of the device 10 include the sensor assembly 20, electronics package 30 and batteries 40.

The electronics package 30 is a simple commercially-available electronics package which will be used to detect and amplify the electrical signal, provide any simple logic required, and store the data. A commercially available Class II Bluetooth (or any other commercially available device) compatible transceiver will transmit the data to a computer, PDA or process tool. The transceiver is part of the electronics package in the case of the wireless operation. Power to the device will be provided by common alkali hydride watch batteries.

In an alternate mode (referred to as the “tethered option”), data is transmitted over a communications wire to an external process computer, PDA or process tool. In this case, there is no transceiver in the electronics package.

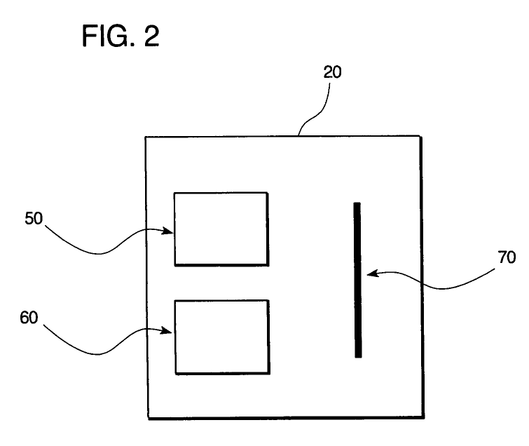

A preferred embodiment of the sensor assembly 20 is shown in FIG. 2. Major components of the sensor assembly 20 include the Ion Sensitive Field Effect Transistor (ISFET) 50, the Reference Field Effect Transistor (REFET) 60, and the counter electrode 70.

The REFET 60 is an ISFET with an additional layer of material over the ion sensitive dielectric, which renders it ion insensitive. The function of the REFET is to compensate for non-chemical variations that would otherwise affect the change in the potential of the sensor assembly.

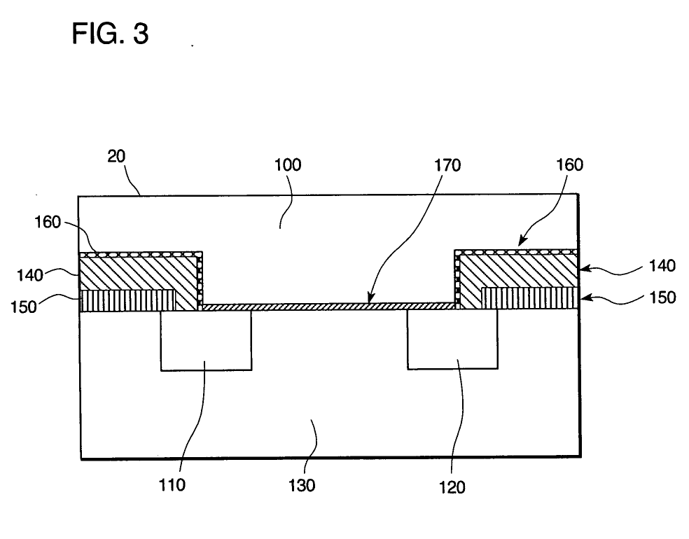

Referring to FIG. 3, a cross sectional cutaway view of the ISFET 20 is shown. Key components of the ISFET 20 are the electrolyte 100, source 110, drain 120, substrate 130, metal 140, oxide 150, ion insensitive insulator 160, and the ion sensitive dielectric 170.

Referring further to FIG. 3, the ISFET 20 is of currently standard design with a gate ion sensitive insulator 170 exposed to the analyte or electrolyte 100. The ion sensitive insulator 170 is composed generally of silicon nitride (SiN) when pH is being tested or a modified silicon nitride when metals or organics are being tested. Other non-native insulators may also be used here.

The reference electrode provides the potential to which the field effect transistor (FET) signal is referenced, and consists of a REFET with a polysilicon or Pt counter electrode referenced together with simple electronics. Alternatively, the reference electrode can be a micro version of standard electrochemical reference electrode.

Theory of Operation

The basic theory of operation of the device 10 is that it designed to be immersed and suspended in the chemical solution or bath that it is monitoring. Alternatively, the device can be affixed to the bath structure.

The device 10 is designed such that it will continuously monitor the level of impurities in a bath and either transmit these data to a receiver outside the bath or store the data internally for subsequent interrogation.

The operation principle of the ISFET 20 is identical to a standard metal oxide semiconductor field effect transistor (MOSFET) component, except that the gate metal in a MOSFET is replaced by an electrolyte and reference electrode. To add a little more detail, in either component, a surface potential is forms at the interface between the gate (metal or electrolyte) and the insulator (in the case of the ISFET, silicon nitride or other non-native insulators). This potential proportionally increases or decreases the number of electron-hole pairs in the depletion region beneath the gate insulator. As a result, the current flow between the source and drain of the device increases or decreases proportionally with the number of hole-electron pairs in the depletion region, resulting in a signal from the FET (either type) that is proportional to the magnitude of the charge at the surface of the insulator. In the simplest case of the ISFET, the charge varies with the hydronium ion concentration, i.e. pH. If the insulator is chemically modified (ChemFET), the surface charge can be made insensitive to pH and sensitive to other charged species (e.g., metal ions).

The REFET 60 is identical to the ISFET, except that it is rendered chemically insensitive by modifying the insulator. Changes in the hole-electron pair concentration in the depletion region are limited to things like temperature and cosmic radiation. The compensation should be identical if the dimensions of the REFET are identical to the ISFET within the operating ranges of semiconductor processing (atmospheric pressure and temperatures) supported by aqueous and semiaqueous solutions.

Additional metrology and associated process control can be obtained by introducing CHEMFETs into the chemical process bath in order to monitor/control other attributes of the chemical bath.

The following is claimed:

1. A device for performing chemical determinations such as measuring component concentrations and metallic impurity concentrations in wet chemical processes and transmitting the data from said determinations, comprising:
a. at least one ion sensitive field effect transistor (ISFET);
b. a reference electrode;
c. a counter electrode;
d. an electronic package to detect and amplify signals produced by ISFET and reference electrode;
e. a transceiver to transmit data to a computer or other process control device; and
f. a power source to provide power to the device.

2. The device in accordance with claim 1, wherein said reference electrode is a reference field effect transistor (REFET).

3. The device in accordance with claim 1 wherein said reference electrode and said ISFET are exposed to the chemical processes they are monitoring.

4. The device in accordance with claim 2 wherein said REFET and ISFET are exposed to the chemical processes they are monitoring.

5. The device in accordance with claims 1 through 4 where the power source is supplied by batteries internal to the device.

6. The device in accordance with claims 1 through 4 where the transceiver is wireless.

7. The device in accordance with claims 1 through 4 where the transceiver transmits data to the process control computer via a wire.

8. A device for performing chemical determinations such as measuring component concentrations and metallic impurity concentrations in wet chemical processes and transmitting the data from said determinations, comprising:
a. at least one chemical field effect transistor (ChemFET);
b. a reference electrode;
c. a counter electrode;
d. an electronic package to detect and amplify signals produced by the ChemFET and reference electrode;
e. a transceiver to transmit data to a computer or other process control device; and
f. a power source to provide power to the device.

9. The device in accordance with claim 8, wherein said reference electrode is a reference field effect transistor (REFET).

10. The device in accordance with claim 8 wherein said reference electrode and said ChemFET are exposed to the chemical processes they are monitoring.

11. The device in accordance with claim 9 wherein said REFET and ChemFET are exposed to the chemical processes they are monitoring.

12. The device in accordance with claims 8 through 11 where the power source is supplied by batteries internal to the device.

13. The device in accordance with claims 8 through 11 where the transceiver is wireless.

14. The device in accordance with claims 8 through 11 where the transceiver transmits data to the process control computer via a wire.

15. A device for performing chemical determinations such as measuring component concentrations and metallic impurity concentrations in wet chemical processes and storing the data from said determinations, comprising:
a. at least one ion sensitive field effect transistor (ISFET);
b. a reference electrode;
c. a counter electrode;
d. an electronic package to detect, amplify, and store signals produced by ISFET and reference electrode;
e. a power source to provide power to the device.

16. The device in accordance with claim 15, wherein said reference electrode is a reference field effect transistor (REFET).

17. The device in accordance with claim 15 wherein said reference electrode and said ISFET are exposed to the chemical processes they are monitoring.

18. The device in accordance with claim 16 wherein said REFET and ISFET are exposed to the chemical processes they are monitoring.

19. The device in accordance with claims 15 through 18 where the power source is supplied by batteries internal to the device.

20. A device for performing chemical determinations such as measuring component concentrations and metallic impurity concentrations in wet chemical processes and storing the data from said determinations, comprising:
a. at least one chemical field effect transistor (ChemFET);
b. a reference electrode;
c. a counter electrode;
d. an electronic package to detect, amplify, and store signals produced by ISFET and reference electrode; and
e. a power source to provide power to the device.

21. The device in accordance with claim 20, wherein said reference electrode is a reference field effect transistor (REFET).

22. The device in accordance with claims 20 wherein said reference electrode and said ChemFET are exposed to the chemical processes they are monitoring.

23. The device in accordance with claim 21 wherein said REFET and ChemFET are exposed to the chemical processes they are monitoring.

24. The device in accordance with claims 20 through 23 where the power source is supplied by batteries internal to the device.
